(19) United States
(12) Patent Application Publication
(10) Pub. No.: US 2025/0040317 A1
(43) Pub. Date: Jan. 30, 2025

(54) DISPLAY APPARATUS AND DISPLAY PANEL

(71) Applicant: BOE Technology Group Co., Ltd., Beijing (CN)

(72) Inventors: Yanan NIU, Beijing (CN); Yan QU, Beijing (CN); Dongni LIU, Beijing (CN); Jinqian WANG, Beijing (CN); Jing NIU, Beijing (CN); Tingting ZHOU, Beijing (CN); Shuang SUN, Beijing (CN); Bin QIN, Beijing (CN); Hongwei TIAN, Beijing (CN); Fangzhen ZHANG, Beijing (CN); Wei WANG, Beijing (CN)

(21) Appl. No.: 18/272,570

(22) PCT Filed: Jun. 29, 2022
(86) PCT No.: PCT/CN2022/102427

§ 371 Date: Jul. 15, 2023

(51) Int. Cl. H01L 33/56; H01L 25/16; H01L 33/62

(52) U.S. Cl. CPC H01L 33/56; H01L 25/167; H01L 33/62

(57) ABSTRACT

The present disclosure provides a display apparatus and a display panel. The display panel includes: a drive backplate, including a substrate and a drive circuit layer on the substrate, where the drive circuit layer includes drive circuit regions arranged at intervals and transparent regions around the drive circuit regions, the transparent region includes concave parts, and a number of layers in the respective concave parts of the drive circuit layer is less than a number of layers in the respective drive circuit regions; a side of the drive circuit regions of the drive circuit layer away from the substrate includes pads for connecting a light-emitting unit; a light-transmissive glue for filling the concave parts, and a surface of the light-transmissive glue away from the substrate is on a side of the pads away from the substrate. The present disclosure can improve display effect.

### TECHNICAL FIELD

The present disclosure relates to the field of display technologies, and in particular to a display apparatus and a display panel.

### BACKGROUND

With rapid development of display technologies, various types of display apparatuses gradually enter the market. Transparent display panel has gained more and more attention because of its unique performance, and has been widely used in window display, car navigation display and other products. However, existing transparent display panels have poor display effect.

### SUMMARY

The purpose of the present disclosure is to provide a display apparatus and a display panel, which can improve display effect.

According to an aspect of the present disclosure, a display panel is provided, where the display panel includes:
a drive backplate, including a substrate and a drive circuit layer on the substrate, where the drive circuit layer includes drive circuit regions arranged at intervals and a transparent region around the drive circuit regions, the transparent region includes concave parts, and a number of layers in the respective concave parts of the drive circuit layer is less than a number of layers in the respective drive circuit regions; a side of the drive circuit regions of the drive circuit layer away from the substrate includes pads for connecting a light-emitting unit;
a light-transmissive glue for filling the concave parts, and a surface of the light-transmissive glue away from the substrate is on a side of the pads away from the substrate.

Further the light-transmissive glue includes a first surface and a second surface opposite to the first surface in a thickness direction of the substrate; a refractive index of the light-transmissive glue increases first and then decreases from the first surface to the second surface.

Further the light-transmissive glue includes a first low-refraction layer, a high-refraction layer and a second low-refraction layer arranged in a stack manner, where refractive indexes of the first low-refraction layer and the second refraction layer are smaller than a refractive index of the high-refraction layer.

Further, at least one of: a difference between refractive indexes of the high-refraction layer and the first low-refraction layer is 0.3-1.3; or
a difference between refractive indexes of the high-refraction layer and the second low-refraction layer is 0.3-1.3.

Further, the refractive index of the first low-refraction layer is 1.2-1.5, the refractive index of the second low-refraction layer is 1.2-1.5, and the refractive index of the high-refraction layer is 1.8-2.5.

Further, the light-transmissive glue includes a first surface and a second surface opposite to the first surface in a thickness direction of the substrate; a refractive index of the light-transmissive glue remains constant from the first surface to the second surface.

Further, the refractive index of the light-transmissive glue is in a range from 1.2 to 1.9.

Further, the substrate is at the bottom of the concave parts.

Further, the drive circuit layer includes:
an active layer on the substrate;
a first gate insulating layer on a side of the active layer away from the substrate;
a first gate layer on a side of the first gate insulating layer away from the substrate;
a second gate insulating layer on a side of the first gate layer away from the substrate;
a second gate layer on a side of the second gate insulating layer away from the substrate;
an intermediate insulating layer on a side of the second gate layer away from the substrate;
a first source and drain layer on a side of the intermediate insulating layer away from the substrate;
a first planarization layer on a side of the first source and drain layer away from the substrate;
a first passivation layer on a side of the first planarization layer away from the substrate; the pads are on a side of the first passivation layer away from the substrate; a second passivation layer on a side of the pads away from the substrate;
a second planarization layer on a side of the second passivation layer away from the substrate;
where at least one of the first planarization layer, the first passivation layer, the second passivation layer or the second planarization layer is/are between a bottom of the concave parts and the substrate.

Further, the drive circuit layer includes:
a second planarization layer on a side of the pads away from the substrate, and is provided with openings for exposing the pads, and the light-emitting unit is in the openings and bounded to the pads;
where in a thickness direction of the substrate, a surface of the light-transmissive glue away from the substrate is on a side of the second planarization layer away from the substrate.

Further, in the thickness direction of the substrate, a distance between the surface of the light-transmissive glue away from the substrate and a surface of the planarization layer away from the substrate is in a range from 2 μm to 3 μm.

Further an orthogonal projection of each of the concave parts on the substrate is within an area of an orthogonal projection of the corresponding light-transmissive glue on the substrate, and a distance between a boundary of the orthogonal projection of each of the concave parts on the substrate and a boundary of the orthogonal projection of the corresponding light-transmissive glue on the substrate is in a range from 5 μm to 10 μm.

Further, parts of the drive circuit layer in the drive circuit regions further include a route layer, where the route layer and the pads are at a same layer; the display panel further includes:
a light-shielding layer on a side of the route layer away from the substrate, and the light-shielding layer shields parts of the route layer.

Further, the light-shielding layer is at edges of the drive circuit regions, and is arranged at intervals from the light-emitting unit.

Further, in a thickness direction of the substrate, a thickness of the light-shielding layer is greater than or equal to 2 μm.

Further, the light-emitting unit includes a plurality of pixels, each pixel includes a plurality of sub-pixels, and one of the drive circuit regions is electrically connected to at least one of the plurality of sub-pixels.

Further, the display panel further includes:
an encapsulation glue covering the light-transmissive glue.

According to an aspect of the present disclosure, a display apparatus is provided, where the display apparatus includes the display panel.

According to the display apparatus and the display panel of the present disclosure, the drive circuit layer includes drive circuit regions arranged at intervals and transparent regions around the drive circuit regions, the transparent region includes concave parts. The present disclosure adopts light-transmissive glue to fill in the concave parts, and the surface of the light-transmissive glue away from the substrate is on a side of the pads away from the substrate, so that a problem of remaining gaps in the process that the encapsulation glue covers the light-transmissive glue can be avoided, thereby reducing optical interference and dispersion, avoiding occurrence of transmission rate reduction, and improving uniformity of the transmission rate.

### BRIEF DESCRIPTION OF DRAWINGS

FIG. 1 is a schematic diagram of a display panel in related arts.

FIG. 2 is a schematic distribution diagram of drive circuit regions and transparent regions in a drive backplate according to an embodiment of the present disclosure.

FIG. 3 is a schematic diagram of a display panel of an embodiment of the present disclosure.

FIG. 4 is a schematic diagram of a part of the structure shown in FIG. 3.

FIG. 5 is another schematic diagram of a display panel of an embodiment of the present disclosure.

FIG. 6 is a schematic diagram of a display panel with a light-shielding layer of an embodiment of the present disclosure.

FIG. 7 is a picture of an image displayed by a display panel in related arts.

### REFERENCE NUMERALS

1, substrate; 2, light-transmission glue; 3, first low-refraction layer; 202, high-refraction layer; 203, second low-refraction layer; 3, first gate insulating layer; 4, first gate layer; 5, second gate insulating layer; 6, second gate layer; 7, intermediate insulating layer; 8, first source and drain layer; 9, first planarization layer; 10, first passivation layer; 11, second passivation layer; 12, pad; 13, second planarization layer; 14, first route layer; 15, second route layer; 16, active layer; 17, sub-pixel; 18, encapsulation glue; 19, light-shield layer; 20, groove; 100, drive circuit region; 200, transparent region.

### DETAILED DESCRIPTION

Description will now be made in detail to illustrative embodiments, examples of which are shown in the accompanying drawings. When the following description refers to the drawings, unless otherwise indicated, the same numbers in different drawings indicate the same or similar elements. Embodiments described in the following illustrative embodiments do not represent all embodiments consistent with the present disclosure. In contrary, they are merely examples of apparatuses consistent with some aspects of the present disclosure as described in detail in the appended claims.

The terminologies used in the present disclosure are for the purpose of describing specific embodiments only and are not intended to limit the present disclosure. Unless otherwise defined, technical terms or scientific terms used in the present disclosure shall have their ordinary meanings as understood by those of ordinary skills in the field to which the present disclosure belongs. The “first”, “second” and similar words used in the specification and claims of the present disclosure do not indicate any order, quantity or importance, but are only used to distinguish different components. Similarly, similar words such as “a” or “one” do not mean quantity limitation, but mean that there is at least one. “Multiple” or “a plurality of” means two or more. Unless otherwise specified, similar words such as “front”, “rear”, “lower” and/or “upper” are only for convenience of explanation, and are not limited to a position or a spatial orientation. Similar words such as “include” or “include” mean that the elements or objects appear before “include” or “include” cover the elements or objects listed after “include” or “comprise” and their equivalents, but do not exclude other elements or objects. Similar words such as “connected” or “connect” are not limited to physical or mechanical connection, but may include electrical connection, whether direct or indirect. Singular forms “a”, “the” and “said” used in the specification of the present disclosure and the appended claims are also intended to include plural forms, unless the context clearly indicates other meaning. It should also be understood that the term “and/or” as used herein refers to and includes any or all possible combinations of one or more associated listed items.

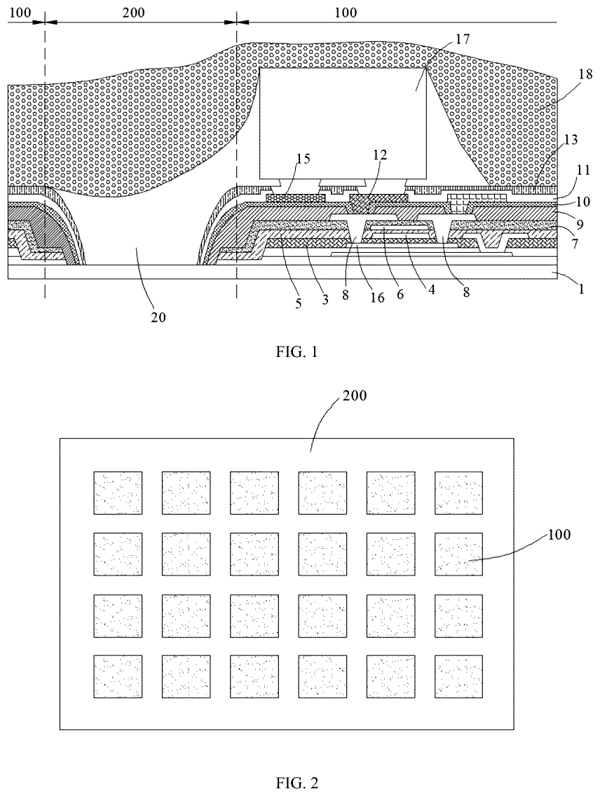

In related arts, as shown in FIG. 1, to improve light transmittance of a display panel to achieve transparent display, grooves 20 are formed in part of regions of the display panel, which are then filled up by sticking encapsulation glue 18. A distance between a bottom of the grooves 20 and top of sub pixels 17 is large, and thickness of the adopted encapsulation glue 18 is 75 μm-250 μm, which results in difficulty in using the encapsulation layer 18 to cover the bottom of the grooves 20, hence gaps are remained in the grooves 20 and spotted air bubbles are formed, and sizes of the bubbles are hard to control, which further results in optical interference (as shown in FIG. 7) and dispersion, and transmission rate reduction and non-uniformity of the transmission rate.

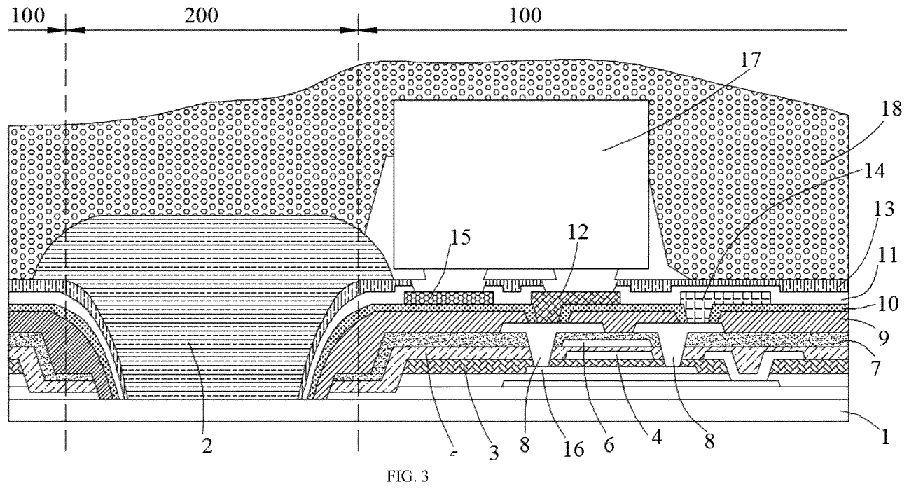

Embodiments of the present disclosure provides a display panel. As shown in FIGS. 2 and 3, the display panel may include a drive backplate, a light-transmissive glue 2 and an encapsulation glue 18.

The drive backplate includes a substrate 1 and a drive circuit layer on the substrate 1. The drive circuit layer includes drive circuit regions 100 arranged at intervals and a transparent region 200 around the drive circuit regions 100. Concave parts are in the transparent region 200, and a number of layers in the respective concave parts of the drive circuit layer is less than a number of layers in the respective drive circuit regions 100. Pads 12 for connecting a light-emitting unit are on a side of the drive circuit regions 100 of the drive circuit layer away from the substrate 1. The light-transmissive glue 2 is used to fill the concave parts, and a surface of the light-transmissive glue 2 away from the substrate 1 is on a side of the pads 12 away from the substrate 1.

According to the display panel of embodiments of the present disclosure, the drive circuit layer includes drive circuit regions 100 arranged at intervals and a transparent region 200 around the drive circuit regions 100, concave parts are in the transparent region 200. The present disclosure adopts the light-transmissive glue 2 to fill in the concave parts, and the surface of the light-transmissive glue 2 away from the substrate 1 is on a side of the pads 12 away from the substrate 1, so that a problem of remaining gaps in the process that the encapsulation glue 18 covers the light-transmissive glue 2 can be avoided, thereby reducing optical interference and dispersion, avoiding occurrence of transmission rate reduction, and improving uniformity of the transmission rate, and improving display effect.

In the following, respective parts of the display panel of the embodiments of the present disclosure will be described in detail.

As shown in FIG. 3, the drive backplate includes the substrate 1 and the drive circuit layer. The substrate 1 may be a rigid substrate. The rigid substrate may include glass substrate or PMMA (Polymethylmethacrylate) substrate, etc. Certainly, the substrate 1 may also be a soft substrate. The soft substrate may include PET (Polyethylene terephthalate) substrate, PEN (Polyethylene naphthalate two formic acid glycol ester) substrate or PI (Polyimide) substrate.

The drive circuit layer may be on the substrate 1. For example, the drive circuit layer may include an active layer 16, a first gate insulating layer 3, a first gate layer 4, a second gate insulating layer 5, a second gate layer 6, an intermediate insulating layer 7, a first source and drain layer 8, a first planarization layer 9, a first passivation layer 10, pads 12, a second passivation layer 11 and a second planarization layer 13. The active layer 16 may be on the substrate 1. The first gate insulating layer 3 may be on a side of the active layer 16 away from the substrate 1. The first gate layer 4 may be on a side of the first gate insulating layer 3 away from the substrate 1. The second gate insulating layer 5 may be on a side of the first gate layer 4 away from the substrate 1. The second gate layer 6 may be on a side of the second gate insulating layer 5 away from the substrate 1. The intermediate insulating layer 7 may be on a side of the second gate layer 6 away from the substrate 1. The first source and drain layer 8 may be on a side of the intermediate insulating layer 7 away from the substrate 1, and may be connected to the active layer 16 through a via sequentially penetrating through the intermediate insulating layer 7, the second gate insulating layer 5 and the first gate insulating layer 3. The first planarization layer 9 may be provided on a side of the first source and drain layer 8 away from the substrate 1. The first passivation layer 10 may be provided on a side of the first planarization layer 9 away from the substrate 1. The pads 12 may be provided on a side of the first passivation layer 10 away from the substrate 1, and may be connected to the first source and drain layer 8 by penetrating through the first passivation layer 10 and the first planarization layer 9. The second passivation layer 11 may be provided on a side of the pads 12 away from the substrate 1. The second planarization layer 13 may be provided on a side of the second passivation layer 11 away from the substrate 1. The second planarization layer 13 and the second passivation layer 11 may be provided with openings for exposing the pads 12, and the light-emitting unit may be in the openings and bounded to the pads 12. The first source and drain layer 8 may include a source electrode and a drain electrode. Each pad 12 may be connected to one of the source electrode and the drain electrode. The drive circuit regions 100 of the drive circuit layer may further include a route layer. The route layer and the pads 12 may be in a same layer. The route layer may include a first route layer 14 and a second route layer 15. The first route layer 14 may adopts Vdd routing, and the second route layer 15 may adopts Vss routing, which is not limited in the present disclosure. The pad 12 may be connected to one of the source electrode and the drain electrode, and the second route layer 15 may be connected to the other one of the source electrode and the drain electrode. The light-emitting unit may include a plurality of pixels, and each pixel may include a plurality of sub-pixels 17. The sub-pixel 17 may be a mini light emitting diode (abbreviated as Mini LED), and the size of which is about 100-300 μm. Certainly, the sub-pixel 17 may also be a micro light emitting diode (abbreviated as Micro LED), and the size of which is smaller than 100 μm.

In a direction parallel to the substrate 1, as shown in FIG. 2, the drive circuit layer may include drive circuit regions 100 arranged at intervals and a transparent region 200 around the drive circuit regions. The active layer 16, the first gate layer 4, the second gate layer 6, the first source and drain layer 8, the route layer and the pads 12 are all in the drive circuit regions 100. Further, the first gate insulating layer 3, the second gate insulating layer 5 and the intermediate insulating layer 7 are also in the drive circuit regions 100. The first planarization layer 9 may only cover the drive circuit regions 100, and certainly, may also cover both the drive circuit regions 100 and the transparent region 200. The first passivation layer 10 may only cover the drive circuit regions 100, and certainly, may also cover both the drive circuit regions 100 and the transparent region 200. The second planarization layer 13 may only cover the drive circuit regions 100, and certainly, may also cover both the drive circuit regions 100 and the transparent region 200. The second passivation layer 11 may only cover the drive circuit regions 100, and certainly, may also cover both the drive circuit regions 100 and the transparent region 200. In addition, one drive circuit region 100 may be provided with a plurality of pads 12, so as to connect the drive circuit region 100 to a plurality of sub-pixels 17. Color of the light emitted by the plurality of sub-pixels 17 connected to one drive circuit region 100 may be different, or certainly may be the same. When color of the light emitted by the plurality of sub-pixels 17 connected to one drive circuit region 100 is different, the plurality of sub-pixels 17 may include a red sub-pixel, a blue sub-pixel and a green sub-pixel, so the light emitted by the plurality of sub-pixels 17 can form white light.

Concave parts are in the transparent region 200. The substrate 1 may be at a bottom of the concave parts, that is, the substrate 1 is exposed at the bottom of the concave parts, that is, the concave parts are not provided with respective layers in the drive circuit regions 100. In other embodiments of the present disclosure, at least one of the first planarization layer 9, the first passivation layer 10, the second planarization layer 13 or the second passivation layer 11 is/are between the bottom of the concave parts and the substrate 1.

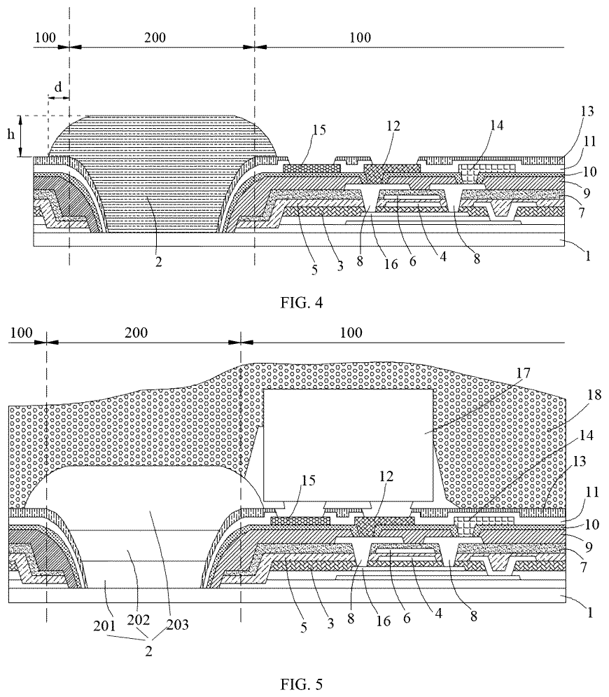

The light-transmissive glue 2 is filled in the concave parts, and a surface of the light-transmissive glue 2 is on a side of the pads 12 away from the substrate 1. That is, in a direction perpendicular to the substrate 1, the light-transmissive glue 2 is higher than the pads 12. In such arrangement, a segment difference between the light-transmissive glue 2 and the sub pixel 17 can be reduced, so as to planarize the transparent region 200 and reduce generation of gaps. In a thickness direction of the substrate 1, a distance between a surface of the light-transmissive glue 2 away from the substrate 1 and a surface of the pad 12 away from the substrate 1 is smaller than or equal to 3 μm, for example, 1 μm, 1.5 μm, 1.8 μm, 3 μm, etc. Further, the surface of the light-transmissive glue 2 away from the substrate 1 is on a side of the second planarization layer 13 away from the substrate. Specifically, in a thickness direction of the substrate 1, as shown in FIG. 4, a distance h between a surface of the light-transmissive glue 2 away from the substrate 1 and a surface of the second planarization layer 13 away from the substrate 1 is 2 μm-3 μm, for example, 2 μm, 2.5 μm, 2.8 μm, 3 μm, etc. An orthogonal projection of each of the concave parts on the substrate 1 may be within an area of an orthogonal projection of the corresponding light-transmissive glue 2 on the substrate 1, that is, an orthogonal projection area of the corresponding light-transmissive glue 2 on the substrate 1 is larger than an orthogonal projection area of the concave part on the substrate 1, and a distance d between a boundary of the orthogonal projection of each of the concave parts on the substrate 1 and a boundary of the orthogonal projection of the corresponding light-transmissive glue 2 on the substrate 1 is 5 μm-10 μm, for example, 5 μm, 6 μm, 7.5 μm, 10 μm, etc. An edge of the light-transmissive glue 2 outside the concave part is uneven, which is easy to become a slope, and the slope may cause interference of equal thickness or inclination, and then serious ripples may appear. In the present disclosure, the distance between the orthogonal projection boundary of each of the concave parts on the substrate 1 and the orthogonal projection boundary of the corresponding light-transmissive glue 2 on the substrate 1 is set to be 5 μm-10 μm, so as to expand the distance between the orthogonal projection boundary of the concave part on the substrate 1 and the orthogonal projection boundary of the corresponding light-transmissive glue 2 on the substrate 1, and reduce the interference caused by the edge of the light-transmitting glue 2, and reduce probability that light incident from the edge of the light-transmissive glue 2 passes through the concave parts.

The light-transmissive glue 2 may include a first surface and a second surface opposite to the first surface in a thickness direction of the substrate 1. The first surface may be between the second surface and the substrate 1, and certainly, the second surface may be between the first surface and the substrate 1. As shown in FIG. 3, the light-transmissive glue 2 has a uniform refractive index, that is, a value of the refractive index of the light-transmissive glue 2 remains constant from the first surface to the second surface, that is, the light-transmissive glue 2 is a single-layer; specifically, the refractive index of the light-transmissive glue 2 may be 1.2-1.9, for example, 1.2, 1.4, 1.5, 1.8, 1.9, etc.; a material of the light-transmissive glue may include polyimide, or acrylic, etc. In other embodiments of the present disclosure, the refractive index of the light-transmissive glue 2 increases first and then decreases from the first surface to the second surface, that is, in a thickness direction of the substrate 1, a refractive index of an intermediate part of the light-transmissive glue 2 is greater than the refractive indexes of both ends of the light-transmissive glue 2. For example, as shown in FIG. 5, the light-transmissive glue 2 may include a first low-refraction layer 201, a high refraction layer 202 and a second low-refraction layer 203 arranged in a stack manner. A surface of the first low-refraction layer 201 away from the high-refraction layer 202 is the first surface, and a surface of the second low-refraction layer 203 away from the high-refraction layer 202 is the second surface. The refractive indexes of the first low-refraction layer 201 and the second low-refraction layer 203 are both smaller than the refractive index of the high-refraction layer 202. A difference between the refractive index of the high-refraction layer 202 and the first low-refraction layer 201 may be 0.3-1.3. A difference between the refractive index of the high-refraction layer 202 and the second low-refraction layer 203 may be 0.3-1.3. The refractive index of the first low-refraction layer 201 may be 1.2-1.5, for example, 1.2, 1.3, 1.4, 1.5, etc. The refractive index of the second low-refraction layer 203 may be 1.2-1.5, for example, 1.2, 1.3, 1.4, 1.5, etc. The refractive index of the second low-refraction layer 203 may be same as the refractive index of the first low-refraction layer 201, and certainly, the refractive index of the second low-refraction layer 203 may also be different. The refractive index of the high-refraction layer 202 may be 1.8-2.5, for example, 1.8, 1.9, 2.1, 2.4, 2.5, etc. In addition, the display panel of the present disclosure may include an encapsulation glue 18. The encapsulation glue 18 covers the light-transmissive glue 2.

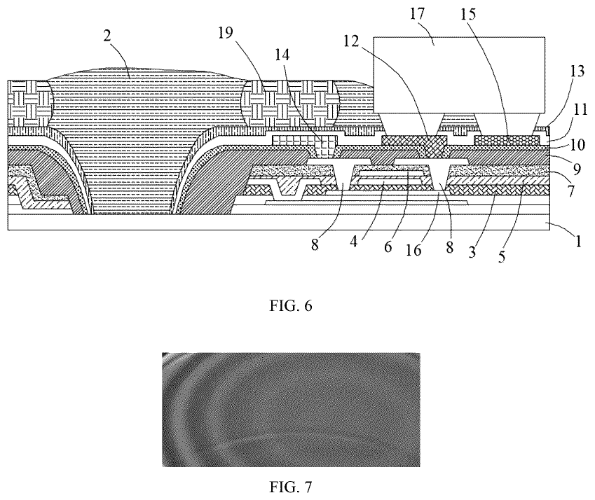

As shown in FIG. 6, the display panel of the present disclosure may further include a light-shielding layer 19. The light-shielding layer 19 may on a side of the route layer away from the substrate 1, and specifically, the light-shielding layer 19 may be on a side of the second planarization layer 13 away from the substrate 1, and may cover part of the route layer, so as to shield light reflected by the route layer. The light-shielding layer 19 may be on edges of the concave parts, that is, the light-shielding layer 19 may be on edges of the drive circuit regions 100, and the light-shielding layer 19 may arranged at intervals from the sub-pixels 17 in a direction parallel to the substrate 1. In such arrangement, in a process of filling glue into the concave parts to form the light-transmissive glue 2, the light-shielding layer 19 may block the glue. In the thickness direction of the substrate 1, a height of the light-shielding layer 19 may be approximately same as or slightly lower than a height of the sub-pixel 17, so as to improve planarization of the drive circuit regions 100. In other embodiments of the present disclosure, in the thickness direction of the substrate 1, the light-shielding layer 19 may be higher than the sub-pixel 17. Specifically, a thickness of the light-shielding layer 19 may be greater than or equal to 2 μm. In such arrangement, not only planarization of the drive circuit regions 100 is improved, but also shielding capability of the light-shielding layer 19 is improved, thereby ensuring low reflectivity of the route layer. It shall be noted that, the display panel with the light-shielding layer 19 may also be provided with the encapsulation glue 18 mentioned above.

Embodiments of the present disclosure further provide a manufacturing method for the display panel. The manufacturing method may include:

In step S10, an active layer is formed in a substrate 1, and a first gate insulating layer 3 is formed on a side of the active layer 1 away from the substrate 1;

In step S20, a first gate layer 4 is formed on a side of the first gate insulating layer 3 away from the substrate 1;

In step S30, a second gate insulating layer 5 is formed on a side of the first gate layer 4 away from the substrate 1;

In step S40, a second gate layer 6 is formed on a side of the second gate insulating layer 5 away from the substrate 1;

In step S50, an intermediate insulating layer 7 is formed on a side of the second gate layer 6 away from the substrate 1;

In step S60, a first source and drain layer 8 is formed on a side of the intermediate insulating layer 7 away from the substrate 1;

In step S70, a first planarization layer 9 is formed on a side of the first source and drain layer 8 away from the substrate 1;

In step S80, a first passivation layer 10 is formed on a side of the first planarization layer 9 away from the substrate 1;

In step S90, pads 12 and a route layer are formed on a side of the first passivation layer 10 away from the substrate 1;

In step S100, a second passivation layer 11 covering the pads 12 and the route layer is formed;

In step S110, a second planarization layer 13 is formed on a side of the second passivation layer 11 away from the substrate 1, and openings for exposing the pads 12 are formed.

It should be noted that in the above steps S10-S110, the layer in the transparent region 200 can be etched after each step is completed. Certainly, the layers in the transparent region 200 can also be together etched after all steps are completed. These two etching manners can make the bottom of the concave parts be the substrate 1. In other embodiments of the present disclosure, to ensure a certain distance between the bottom of the concave parts and the substrate, only part of the layers may be etched in the present disclosure.

In addition, after the step S110, the sub-pixels 17 can be bounded, and then the light-transmissive glue can be filled in, and then the encapsulation glue 18 can be sticked in the present disclosure. For the display panel with the light-shielding layer 19, in the present disclosure, the light-shielding layer 19 may be formed before the light-transmissive glue is filled in, and then the light-transmissive glue can be filled in, and then the encapsulation glue 18 can be sticked.

Embodiments of the present disclosure further provide a display apparatus. The display apparatus may include the display panel as mentioned in any one of the above embodiments. The display apparatus may be a mobile phone, and certainly, may also be a tablet computer, a television, etc. The display apparatus may be a spliced display apparatus, and the spliced display apparatus can be formed by splicing a plurality of the display panels. Since the display panel in the display apparatus of the embodiment of the present disclosure is the same as the display panel in the embodiment of the above-mentioned display panel, they have the same beneficial effects, and will not be repeated here.

The above are only preferred embodiments of the present disclosure, and they do not limit the present disclosure in any form. Although the present disclosure has been disclosed in the preferred embodiments, they are not used to limit the present disclosure. Any person familiar with this profession can make some changes or modify it into an equivalent embodiment by using the technical content disclosed above without departing from the scope of the technical solution of the present disclosure. So long as the content does not depart from the technical solution of the present disclosure, any simple modifications, equivalent changes or modifications made to the above embodiments according to the technical essence of the present disclosure belong to the scope of the technical solution of the present disclosure.

1. A display panel, comprising:
a drive backplate, comprising a substrate and a drive circuit layer on the substrate, wherein the drive circuit layer comprises drive circuit regions arranged at intervals and a transparent region around the drive circuit regions, the transparent region comprises concave parts, and a number of layers in the respective concave parts of the drive circuit layer is less than a number of layers in the respective drive circuit regions; a side of the drive circuit regions of the drive circuit layer away from the substrate comprises pads for connecting a light-emitting unit;
a light-transmissive glue for filling the concave parts, and a surface of the light-transmissive glue away from the substrate is on a side of the pads away from the substrate.

2. The display panel according to claim 1, wherein the light-transmissive glue comprises a first surface and a second surface opposite to the first surface in a thickness direction of the substrate; a refractive index of the light-transmissive glue increases first and then decreases from the first surface to the second surface.

3. The display panel according to claim 1, wherein the light-transmissive glue comprises a first low-refraction layer, a high-refraction layer and a second low-refraction layer arranged in a stack manner, wherein refractive indexes of the first low-refraction layer and the second refraction layer are smaller than a refractive index of the high-refraction layer.

4. The display panel according to claim 3, wherein at least one of:
a difference between refractive indexes of the high-refraction layer and the first low-refraction layer is in a range from 0.3 to 1.3; or
a difference between refractive indexes of the high-refraction layer and the second low-refraction layer is in a range from 0.3 to 1.3.

5. The display panel according to claim 4, wherein the refractive index of the first low-refraction layer is in a range from 1.2 to 1.5, the refractive index of the second low-refraction layer is in a range from 1.2 to 1.5, and the refractive index of the high-refraction layer is in a range from 1.8 to 2.5.

6. The display panel according to claim 1, wherein the light-transmissive glue comprises a first surface and a second surface opposite to the first surface in a thickness direction of the substrate; a refractive index of the light-transmissive glue remains constant from the first surface to the second surface.

7. The display panel according to claim 6, wherein the refractive index of the light-transmissive glue is in a range from 1.2 to 1.9.

8. The display panel according to claim 1, wherein the substrate is at a bottom of the concave parts.

9. The display panel according to claim 1, wherein the drive circuit layer comprises:
an active layer on the substrate;
a first gate insulating layer on a side of the active layer away from the substrate;
a first gate layer on a side of the first gate insulating layer away from the substrate;
a second gate insulating layer on a side of the first gate layer away from the substrate;
a second gate layer on a side of the second gate insulating layer away from the substrate;
an intermediate insulating layer on a side of the second gate layer away from the substrate;
a first source and drain layer on a side of the intermediate insulating layer away from the substrate;
a first planarization layer on a side of the first source and drain layer away from the substrate;
a first passivation layer on a side of the first planarization layer away from the substrate; the pads are on a side of the first passivation layer away from the substrate;
a second passivation layer on a side of the pads away from the substrate;
a second planarization layer on a side of the second passivation layer away from the substrate;
wherein at least one of the first planarization layer, the first passivation layer, the second passivation layer or the second planarization layer is/are between a bottom of the concave parts and the substrate.

10. The display panel according to claim 1, wherein the drive circuit layer comprises:
a second planarization layer on a side of the pads away from the substrate, and is provided with openings for exposing the pads, and the light-emitting unit is in the openings and bounded to the pads;
wherein in a thickness direction of the substrate, a surface of the light-transmissive glue away from the substrate is on a side of the second planarization layer away from the substrate.

11. The display panel according to claim 10, wherein in the thickness direction of the substrate, a distance between the surface of the light-transmissive glue away from the substrate and a surface of the second planarization layer away from the substrate is in a range from 2 μm to 3 μm.

12. The display panel according to claim 1, wherein an orthogonal projection of each of the concave parts on the substrate is within an orthogonal projection of the corresponding light-transmissive glue on the substrate, and a distance between a boundary of the orthogonal projection of each of the concave parts on the substrate and a boundary of the orthogonal projection of the corresponding light-transmissive glue on the substrate is in a range from 5 μm to 10 μm.

13. The display panel according to claim 1, wherein parts of the drive circuit layer in the drive circuit regions further comprise a route layer, wherein the route layer and the pads are at a same layer; the display panel further comprises:
a light-shielding layer on a side of the route layer away from the substrate, and the light-shielding layer shields parts of the route layer.

14. The display panel according to claim 13, wherein the light-shielding layer is at edges of the drive circuit regions, and is arranged at intervals from the light-emitting unit.

15. The display panel according to claim 13, wherein in a thickness direction of the substrate, a thickness of the light-shielding layer is greater than or equal to 2 μm.

16. The display panel according to claim 1, wherein the light-emitting unit comprises a plurality of pixels, each pixel comprises a plurality of sub-pixels, and one of the drive circuit regions is electrically connected to at least one of the plurality of sub-pixels.

17. The display panel according to claim 1, wherein the display panel further comprises:
an encapsulation glue covering the light-transmissive glue.

18. A display apparatus, comprising the display panel according to claim 1.
